(19) United States
(12) Patent Application Publication
(10) Pub. No.: US 2025/0185471 A1
(43) Pub. Date: Jun. 5, 2025

(54) DISPLAY DEVICE

(71) Applicant: LG Display Co., Ltd., Seoul (KR)

(72) Inventors: Byungjun LIM, Paju-si (KR); Youngsun JANG, Paju-si (KR)

(21) Appl. No.: 18/807,277

(22) Filed: Aug. 16, 2024

(30) Foreign Application Priority Data
Nov. 30, 2023 (KR) 10-2023-0170639

(51) Int. Cl. H10K 59/124; H10K 59/40; H10K 59/80

(52) U.S. Cl. CPC H10K 59/124; H10K 59/40; H10K 59/873

(57) ABSTRACT

A display device according to an embodiment of the present specification may include a substrate including a display area and a non-display area adjacent to the display area. The display device includes a first insulating layer on the substrate, a second insulating layer on the first insulating layer. The display device also includes a plurality of pattern structures formed to be spaced apart each other on the second insulating layer in the non-display area. The display device includes a support layer on each pattern structure of the plurality and includes an organic material. The display device includes an organic layer on the first insulating layer. The organic layer disposed on the support layer may be disposed to be spaced apart from the organic layer on the first insulating layer.

### CROSS REFERENCE TO RELATED APPLICATION

The present application claims priority to Korean Patent Application No. 10-2023-0170639, filed on Nov. 30, 2023, the entire contents of which is incorporated herein for all purposes by this reference.

### BACKGROUND

### Technical Field

The present specification relates to a display device.

### Description of the Related Art

As technologies advance, display devices are being applied to various electronic devices, such as TVs, mobile phones, laptops, and tablets, and transportation means. A display device is becoming thinner, lighter, and has lower power consumption, and research for the same is continuously being conducted.

In addition, a mobile phone has a built-in camera, and a screen design of the camera is difficult due to the limitation of the screen design. Therefore, a space required for the camera is formed by forming a hole in the mobile phone.

### BRIEF SUMMARY

While the hole in the mobile phone is beneficial to provide a space for the camera modules or sensors, due to the fact that the hole is formed in the screen of the mobile phone, there may be a problem that the display device is vulnerable to moisture, oxygen, or the like easily deteriorates. Therefore, it is beneficial to have a method for preventing moisture and oxygen from permeating along an end portion of the hole of the display device.

Embodiments of the present specification are directed to providing a display device that addresses the various technical problems in the related art, including the above-identified problem by the inventors. Various embodiments of the display device described herein prevent damage to an element within the display device due to moisture, oxygen, and the like that permeate through a hole from the outside.

The embodiments of the present specification are also directed to providing a display device in which damage to an element can be prevented by effectively disconnecting a path through which moisture, oxygen, and the like.

A display device according to an embodiment of the present specification may include a substrate including a display area and a non-display area, a first insulating layer formed on the substrate, a second insulating layer formed on the first insulating layer, patterns formed to be spaced apart each other on the second insulating layer in the non-display area, a support layer formed on each pattern and made of an organic material, and an organic layer formed on the first insulating layer, in which the support layer may be made of an organic material, and the organic layer disposed on the support layer may be disposed to be spaced apart from the organic layer formed on the first insulating layer.

### BRIEF DESCRIPTION OF THE SEVERAL VIEWS OF THE DRAWINGS

FIG. 1 is a plan view of a display device according to an embodiment of the present specification.

FIG. 2 is an enlarged view of area A in FIG. 1 according to the embodiment of the present specification.

FIG. 3 is a cross-section view of a sub-pixel along line I-I′ in FIG. 1 according to the embodiment of the present specification.

FIG. 4 is a cross-sectional view along line II-II′ in FIG. 2 according to the embodiment of the present specification.

FIG. 5 is an enlarged view of area B in FIG. 4 according to the embodiment of the present specification.

FIG. 6 is a cross-sectional view of a pattern according to the embodiment of the present specification.

### DETAILED DESCRIPTION

Hereinafter, some embodiments of the present specification will be described in detail with reference to exemplary drawings. In adding reference numerals to components in each drawing, the same components may have the same reference numerals as much as possible even when they are shown in different drawings. In addition, in the description of the present specification, when it is determined that a detailed description of a related known configuration or function may obscure the gist of the present specification, detailed description thereof may be omitted. When terms “comprise,” “have,” “consist of,” and the like described in the present specification are used, other parts may be added unless “only” is used. When a component is expressed in the singular, it may include a case where the component is provided as a plurality of components unless specifically stated otherwise.

In addition, in the description of the components of the present specification, terms such as first, second, A, B, (a), and (b) may be used. These terms are only for the purpose of distinguishing one component from another component, and the nature, sequence, order, or the like of the corresponding component is not limited by these terms.

In the description of the positional relationship of components, when two or more components are described as being “connected,” “coupled,” or “joined,” it should be understood that the two or more components are directly “connected,” “coupled,” or “joined,” but two or more components may be “connected,” “coupled,” or “joined” with other components “interposed” therebetween. Here, other components may be included in one or more of the two or more components that are “connected,” “coupled,” or “joined.”

In the description of the temporal flow relationship related to components, operation methods, manufacturing methods, and the like, for example, the temporal sequence relationship or the flow sequence relationship, such as “after,” “subsequent to,” “then,” or “before,” it may also include a non-continuous case unless “immediately” or “directly” is used.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Meanwhile, in case that numerical values of components or the corresponding information (e.g., a level) are described, even when there is no separate explicit description, the numerical values or the corresponding information can be construed as including a range of error that may occur due to various factors (e.g., process factors, an internal or external impact, and noise).

Hereinafter, various embodiments of the present specification will be described in detail with reference to the accompanying drawings.

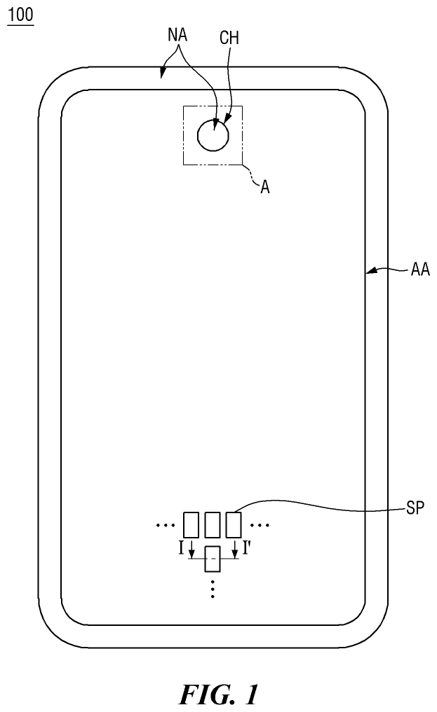

FIG. 1 is a plan view of a display device according to an embodiment of the present specification.

Referring to FIG. 1, a display device 100 may include an optical module and a display panel. For example, the optical module may include a sensor, a camera, and the like, but embodiments of the present specification are not limited thereto.

The display panel may include a display area AA and a non-display area NA. The display area AA may be an area in which images are displayed. For example, the display area AA may be an active area, but the embodiments of the present specification are not limited thereto. The non-display area NA may be located near the display area AA or may surround the display area AA. For example, the non-display area NA may be a non-active area or a bezel area, but embodiments of the present specification are not limited thereto.

The display area AA in the display device 100 may include a plurality of sub-pixels SP. The sub-pixel SP may include a pixel circuit composed of a switching transistor, a driving transistor, an organic light emitting diode, and the like.

The display device 100 according to the embodiment of the present specification may be an organic light emitting diode (OLED) display device, a quantum dot display device, a micro light emitting diode (LED) display device, or the like, but the embodiments of the present specification are not limited thereto.

A through hole CH may be disposed inside the display area AA of the display panel. For example, a sensor may be disposed to correspond to the through hole CH. For example, the sensor may be a distance monitoring sensor or a facial recognition sensor, but the embodiments of the present specification are not limited thereto. Since the sensor may be disposed in the through hole CH, it is possible to decrease the non-display area NA and expand or widen the display area AA. Products with the expanded display area AA can increase the user's screen immersion.

As shown, one through hole CH may be present, but the embodiments of the present specification are not limited thereto. For example, the number and shapes of holes CH may be changed in any of various ways. For example, two or more through holes may be disposed inside the display area AA, a camera may be disposed in a first hole, and sensors, such as a distance detection sensor and a face recognition sensor, may be disposed in a second hole, but the embodiments of the present specification are not limited thereto.

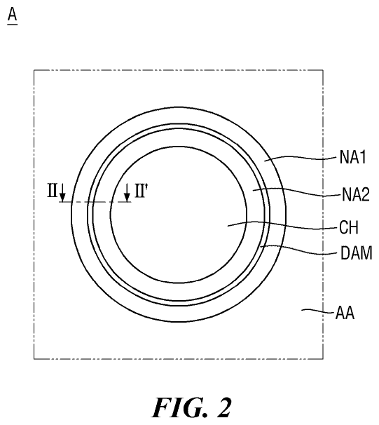

FIG. 2 is an enlarged view of area A in FIG. 1 according to the embodiment of the present specification.

Referring to FIG. 2, area A may include a portion of the display area AA, the non-display area NA, and the through hole CH.

The non-display area NA may include a first non-display area NA1 adjacent to the display area AA, and a second non-display area NA2 adjacent to the through hole CH. For example, the second non-display area NA2 may be located outside the first non-display area NA1.

The first non-display area NA1 may include a dam DAM. For example, the dam DAM and the through hole CH may be disposed to be spaced apart from each other, but are not limited thereto.

The dam DAM may be disposed in a form of surrounding the through hole CH.

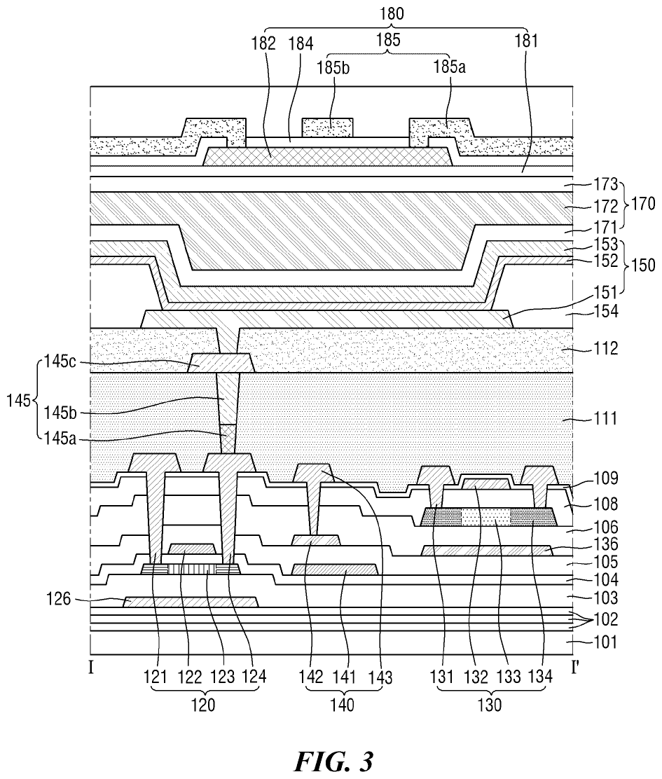

FIG. 3 is a cross-section view of a sub-pixel along line I-I′ in FIG. 1 according to the embodiment of the present specification.

Referring to FIGS. 1 and 3, the display device 100 may include a substrate 101, a buffer layer 102, a first thin film transistor 120, a second thin film transistor 130, a storage electrode 140, a light emitting part 150, an encapsulation part 170, and a touch part 180.

The substrate 101 may include one or more plastic materials. For example, the substrate 101 may be a multi-substrate including a plurality of plastic materials such as polyimide, but is not limited thereto.

The buffer layer 102 may be disposed on the substrate 101. The buffer layer 102 can minimize or delay the diffusion of moisture or oxygen permeating the substrate 101. The buffer layer 102 may be formed by alternately stacking silicon nitride (SiNₓ) and silicon oxide (SiOₓ) at least once, but the embodiments of the present specification are not limited thereto.

A first light blocking layer 126 may be disposed on the buffer layer 102. The first light blocking layer 126 can prevent light from transmitting a first semiconductor layer 123 of the first thin film transistor 120. For example, the first semiconductor layer 123 may be disposed to overlap the first light blocking layer 126. The first light blocking layer 126 may be formed of a single layer or multiple layers made of any one of molybdenum (Mo), aluminum (Al), chromium (Cr), nickel (Ni), neodymium (Nd), and copper (Cu) or an alloy thereof, but is not limited thereto.

A first insulating layer 103 may be disposed on the first light blocking layer 126. The first insulating layer 103 can prevent a short between a component of the first thin film transistor 120 and the first light blocking layer 126. The first insulating layer 103 may be made of the same material as the buffer layer 102, but the embodiments of the present specification are not limited thereto. For example, the first insulating layer 103 may be made of an inorganic material, such as silicon nitride (SiNₓ) or silicon oxide (SiOₓ), but is not limited thereto.

The first thin film transistor 120 may be formed on the first insulating layer 103. The first thin film transistor 120 may include a first source electrode 121, a first gate electrode 122, a first semiconductor layer 123, and a first drain electrode 124.

The first semiconductor layer 123 may be formed on the first insulating layer 103. The first semiconductor layer 123 may include a metal oxide semiconductor, such as indium-gallium-zinc oxide (IGZO), and a silicon-based semiconductor material, such as amorphous silicon or polycrystalline silicon, but is not limited thereto. The first semiconductor layer 123 may include a channel area, a source area, and a drain area.

Since the polycrystalline semiconductor layer has higher mobility than the amorphous semiconductor layer and the oxide semiconductor layer, energy consumption power can be low and reliability can be excellent. Therefore, the driving transistor may be formed of the polycrystalline semiconductor layer.

A second insulating layer 104 may be disposed on the first semiconductor layer 123. The second insulating layer 104 may be made of the same material as the first insulating layer 103 and can prevent a short between the first semiconductor layer 123 and another component of the first thin film transistor 120.

The first gate electrode 122 may be formed on the second insulating layer 104. The first gate electrode 122 may be disposed on the second insulating layer 104 to overlap the channel area of the first semiconductor layer 123. The first gate electrode 122 may be formed of a single layer or multiple layers made of molybdenum (Mo), copper (Cu), titanium (Ti), aluminum (Al), chromium (Cr), gold (Au), nickel (Ni), neodymium (Nd), or compounds thereof. The first gate electrode 122 may be disposed together with gate lines.

A third insulating layer 105 may be disposed on the first gate electrode 122. The third insulating layer 105 may be made of the same material as the first insulating layer 103 or the second insulating layer 104.

The first source electrode 121 and the first drain electrode 124 may be disposed on the third insulating layer 105.

The first source electrode 121 and the first drain electrode 124 may be electrically connected to the first semiconductor layer 123 through contact holes. The first source electrode 121 and the first drain electrode 124 may be made of a metal material. For example, the first source electrode 121 and the first drain electrode 124 may be formed of a single layer or multiple layers made of any one of molybdenum (Mo), aluminum (Al), chromium (Cr), gold (Au), titanium (Ti), nickel (Ni), neodymium (Nd), and copper (Cu) or an alloy thereof, but are not limited thereto.

The first source electrode 121 and the first drain electrode 124 may be disposed together with data lines. For example, the data line may be made of the same material as the first source electrode 121 and the first drain electrode 124 and may be formed coplanarly with the first source electrode 121 and the first drain electrode 124, but is not limited thereto.

The storage electrode 140 may be disposed to be spaced apart from the first thin film transistor 120. The storage electrode 140 may include a first storage electrode 141, a second storage electrode 142, and a third storage electrode 143.

The first storage electrode 141 may be disposed coplanarly with the first gate electrode 122 and may be made of the same material as the first gate electrode 122, but is not limited thereto.

The second storage electrode 142 may be formed on the first storage electrode 141. The second storage electrode 142 may be disposed on the third insulating layer 105, and a capacitance may be generated by a dielectric between the first storage electrode 141 and the second storage electrode 142.

The second storage electrode 142 may be made of the same material as the first storage electrode 141, but is not limited thereto.

The second thin film transistor 130 may be disposed to be spaced apart from the first thin film transistor 120 and the storage electrode 140. The second thin film transistor 130 may include a second source electrode 131, a second gate electrode 132, a second semiconductor layer 133, and a second drain electrode 134.

A second light blocking layer 136 may be disposed coplanarly with the second storage electrode 142.

The second light blocking layer 136 can prevent light directed to the second semiconductor layer 133 similar to the first light blocking layer 126, thereby extending the lifetime of the second thin film transistor 130. For example, the second semiconductor layer 133 may be disposed to overlap the second light blocking layer 136.

A fourth insulating layer 106 may be disposed on the second light blocking layer 136. The fourth insulating layer 106 may be made of the same material as the first insulating layer 103, the second insulating layer 104, or the third insulating layer 105, but is not limited thereto.

The second semiconductor layer 133 may be formed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicon-based semiconductor material, such as amorphous silicon or polycrystalline silicon, but is not limited thereto.

A fifth insulating layer 108 may be disposed on the second semiconductor layer 133. The fifth insulating layer 108 may be made of the same material as the first insulating layer 103, the second insulating layer 104, the third insulating layer 105, or the fourth insulating layer 106, but is not limited thereto.

The second gate electrode 132 may be formed on the fifth insulating layer 108.

The second gate electrode 132 may be made of the same material as the first gate electrode 122. For example, the second gate electrode 132 may be formed of a single layer or multiple layers made of molybdenum (Mo), copper (Cu), titanium (Ti), aluminum (Al), chromium (Cr), gold (Au), nickel (Ni), neodymium (Nd), or compounds thereof, but is not limited thereto.

A sixth insulating layer 109 may be disposed on the second gate electrode 132. The sixth insulating layer 109 may be made of the same material as the first insulating layer 103, the second insulating layer 104, the third insulating layer 105, the fourth insulating layer 106, or the fifth insulating layer 108, but is not limited thereto.

The first source electrode 121, the first drain electrode 124, the third storage electrode 143, the second source electrode 131, and the second drain electrode 134 may be formed on the sixth insulating layer 109.

The third storage electrode 143, the second source electrode 131, and the second drain electrode 134 may be made of the same material as the first source electrode 121 and the first drain electrode 124 and disposed coplanarly with the first source electrode 121 and the first drain electrode 124. For example, the third storage electrode 143, the second source electrode 131, and the second drain electrode 134 may be formed of a single layer or multiple layers made of molybdenum (Mo), aluminum (Al), chromium (Cr), gold (Au), titanium (Ti), nickel (Ni), neodymium (Nd), and copper (Cu) or an alloy thereof, but are not limited thereto.

The first thin film transistor 120 may be a driving transistor, and the second thin film transistor 130 may be a switching transistor, but the embodiments of the present specification are not limited thereto.

A first protective layer 111 may be formed on the first source electrode 121 and the first drain electrode 124.

The first protective layer 111 may planarize an upper portion of the first thin film transistor 120 and protect the first thin film transistor 120. The first protective layer 111 may be made of an organic material. For example, the first protective layer 111 may be made of an organic material containing an acrylic resin, an epoxy resin, a phenolic resin, a polyamide resin, or a polyimide resin, but is not limited thereto.

A second protective layer 112 may be disposed on the first protective layer 111. The second protective layer 112 may be made of the same material as the first protective layer 111, but is not limited thereto.

A connection electrode 145 may be formed between the first protective layer 111 and the second protective layer 112.

The connection electrode 145 may electrically connect the first thin film transistor 120 with the light emitting part 150. The connection electrode 145 may be made of the same material as the first source electrode 121 and the first drain electrode 124, but is not limited thereto.

The thickness of the connection electrode 145 may be greater than the thickness of the first gate electrode 122 of the first thin film transistor 120 and the thickness of the second gate electrode 132 of the second thin film transistor 130.

The connection electrode 145 may include a first metal layer 145a, a second metal layer 145b, and a third metal layer 145c.

The first metal layer 145a and the third metal layer 145c may be made of the same material. For example, the first metal layer 145a and the third metal layer 145c may include titanium (Ti), but are not limited thereto.

The second metal layer 145b may be made of a different material from the first metal layer 145a and the third metal layer 145c. For example, the material of the second metal layer 145b may differ from at least one of the material of the first metal layer 145a and the material of the third metal layer 145c. For example, the second metal layer 145b may include aluminum (Al), but is not limited thereto.

The light emitting part 150 may be formed on the second protective layer 112.

The light emitting part 150 may include an anode 151, a light emitting layer 152, and a cathode 153.

The anode 151 may be formed on the second protective layer 112.

The anode 151 may be electrically connected to the first thin film transistor 120 through a contact hole formed in the second protective layer 112.

The anode 151 may be a reflective electrode that reflects light, but is not limited thereto.

The anode 151 may include a metal material with high reflectivity, such as a stacking structure (Ti/Al/Ti) of aluminum (Al) and titanium (Ti), a stacking structure (ITO/Al/ITO) of aluminum (Al) and indium tin oxide (ITO), or an APC alloy, and may be formed of a single layer or multiple layers, but is not limited thereto.

The light emitting layer 152 may be formed on the anode 151. The light emitting layer 152 may include one or more light emitting structures (or light emitting elements or elements) stacked on the anode 151 in the order or reverse order of a hole transport layer and an electron transport layer.

The light emitting layer 152 may be an organic light emitting layer, an inorganic light emitting layer, a quantum dot light emitting layer, a micro light emitting diode, a micro mini light emitting diode, or the like, but is not limited thereto. For example, the light emitting layer 152 of the display panel 100 according to one embodiment of the present specification may include an organic light emitting layer.

The light emitting layer 152 may include a red light emitting layer, a green light emitting layer, and a blue light emitting layer.

The cathode 153 may be formed on the light emitting layer 152. The cathode 153 may be a transparent electrode that transmits light, but is not limited thereto. For example, the cathode 153 may include a transparent conductive material, such as indium tin oxide (ITO) or indium zinc oxide (IZO), or a metal that transmits visible light.

The bank 154 may be formed to expose the anode 151. The bank 154 may define an opening (or a light emitting area) of the sub-pixel and may be disposed to cover an edge portion of the anode 151. Each sub-pixel may include a red light emitting area, a green light emitting area, and a blue light emitting area. For example, the sub-pixel can be defined as a pixel, but is not limited by the term.

The encapsulation part 170 may be formed on the bank 154 or the light emitting part 150. The encapsulation part 170 may include one or more insulating layers. For example, the encapsulation part 170 may include a first encapsulation layer 171, a second encapsulation layer 172 formed on the first encapsulation layer 171, and a third encapsulation layer 173 formed on the second encapsulation layer 172. The encapsulation part 170 may include one or more inorganic layers and one or more organic layers. For example, the first encapsulation layer 171 and the third encapsulation layer 173 may include an inorganic material, and the second encapsulation layer 172 may include an organic material.

A touch buffer layer 181 may be disposed on the encapsulation part 170. For example, the touch buffer layer 181 may be formed on the third encapsulation layer 173.

The touch buffer layer 181 may be made of the same material as the buffer layer 102.

A touch insulating layer 184 may be formed on the touch buffer layer 181. The touch insulating layer 184 can prevent a short between the touch electrodes. The touch insulating layer 184 may be made of silicon oxide (SiOₓ), silicon nitride (SiNₓ), or multiple layers thereof, but is not limited thereto.

The first touch electrode 185 may be formed on the touch insulating layer 184.

The first touch electrode 185 may include a 1a touch electrode 185a extending in a first direction and a 1b touch electrode 186b extending in a second direction that differs from the first direction.

A second touch electrode 182 may be formed between the touch buffer layer 181 and the touch insulating layer 184.

The second touch electrode 182 may be electrically connected to the 1a touch electrode 185a through a contact hole formed in the touch insulating layer 184. For example, the 1a touch electrode 185a and the second touch electrode 182 may extend in the first direction.

The first touch electrode 185 and the second touch electrode 182 may include a metal material. For example, the first touch electrode 185 and the second touch electrode 182 may be made of titanium (Ti), nickel (Ni), aluminum (Al), or an alloy thereof and may be formed of a triple layer, such as titanium (Ti)/aluminum (Al)/titanium (Ti), but are not limited thereto.

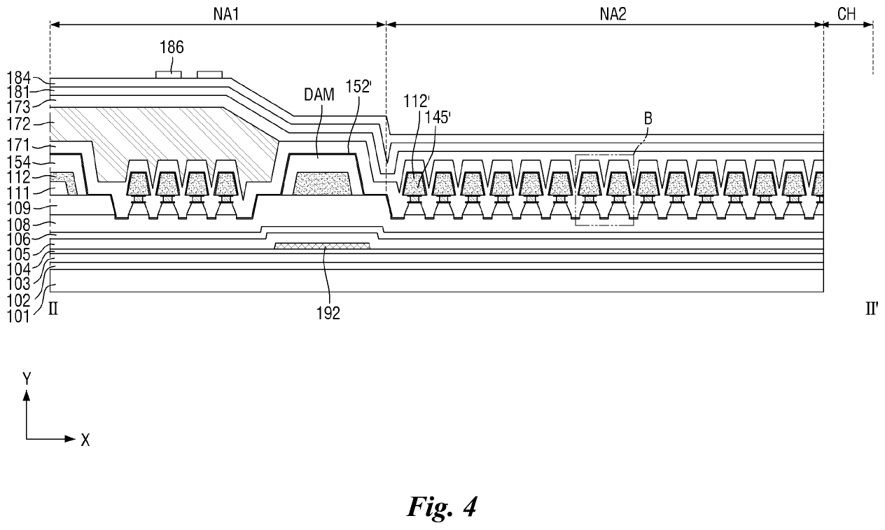

FIG. 4 is a cross-sectional view along line II-II′ in FIG. 2 according to the embodiment of the present specification.

Some of components shown in FIG. 4 are formed by extending the components of the display area AA shown in FIG. 3 to the non-display area NA and may be substantially the same as those of the display area AA.

Referring to FIGS. 2 to 4, the display device 100 according to the embodiment of the present specification may include the substrate 101, the insulating layer formed on the substrate 101, a pattern 145′ (or also referred to as a pattern structure 145′) formed on the insulating layer, and a support layer 112′ formed on the pattern 145′. Hereinafter, descriptions that are substantially the same as those in FIG. 3 will be denoted by the same reference numerals, overlapping descriptions thereof will be omitted, and only parts that differ from those in FIG. 3 will be described.

Referring to FIG. 1 together, although screen immersion can be increased by arranging the through hole CH inside the display area AA to maximize the display area AA, an end portion of the organic layer 152′ may be exposed in a process of forming the through hole CH. Here, the organic layer 152′ may be made of the same material as the light emitting layer 152 of the display area AA and formed coplanarly with the light emitting layer 152.

Therefore, a moisture permeable path may be formed from the end portion of the organic layer 152′ exposed through the through hole CH to the light emitting part 150 of the display area AA. The display panel 100 according to the embodiment of the present specification can block moisture, oxygen, foreign substance, and the like that may move along the moisture permeable path by providing a disconnection structure of the organic layer 152′ or the like.

The dam DAM may be disposed in the first non-display area NA1

The dam DAM may be made of the same material as the second protective layer 112 and the bank 154, and to reduce the non-display area NA, only one dam DAM may be disposed, but the embodiments of the present specification are not limited thereto. In addition, the organic layer 152′ may be disposed to cover the dam DAM. The dam 190 can more effectively prevent the permeation of moisture and oxygen by increasing a distance of the moisture and oxygen permeation path.

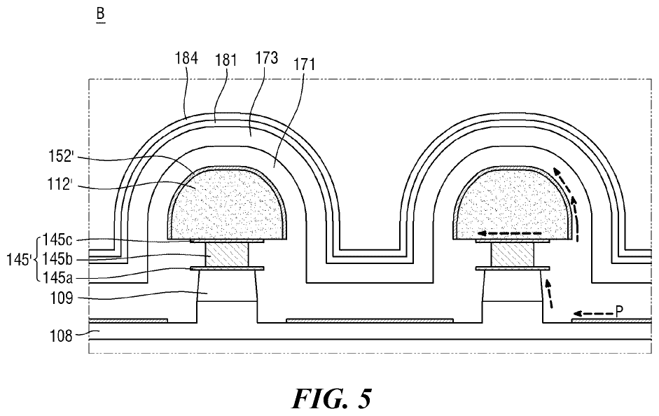

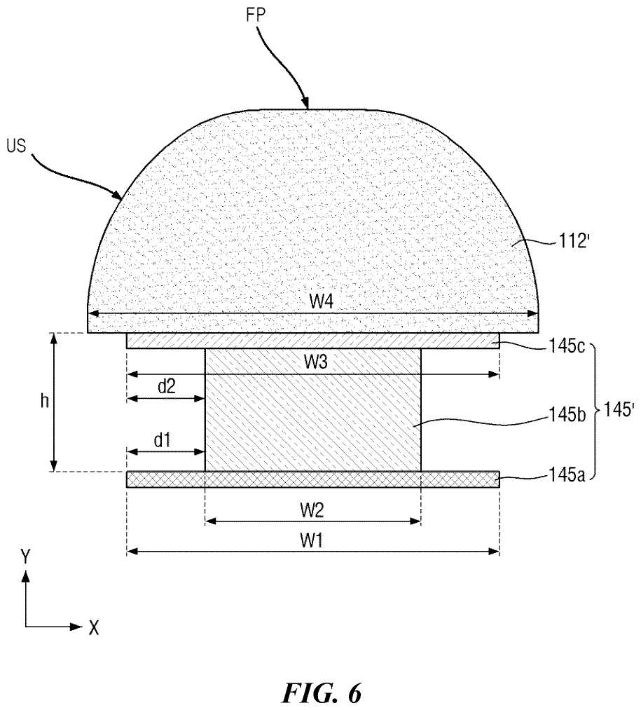

To delay and block the permeation of moisture introduced from the outside through the exposed end portion of the organic layer 152′ and prevent damage to the display panel 100 due to foreign substance, the pattern 145′ may be disposed in the first non-display area NA1 and the second non-display area NA2. The pattern 145′ may be a wire, a line, a metal layer, or the like, but is not limited thereto. A moisture permeation blocking path mechanism will be described below with reference to FIGS. 5 and 6.

The touch buffer layer 181 may be formed throughout the display area AA and the non-display area NA. For example, the touch buffer layer 181 may be formed throughout the first non-display area NA1 and the second non-display area NA2.

A hole crack detection part 186 may be formed on the touch buffer layer 181. For example, the hole crack detection part 186 may be formed in the non-display area NA. For example, the hole crack detection part 186 may be formed in the first non-display area NA1, but is not limited thereto.

The display panel 100 may include the through hole CH in the components formed on the substrate 101 in addition to the substrate 101. The through hole CH may expose the components formed on the substrate 101 in addition to the substrate 101. The components formed on the substrate 101 in addition to the exposed substrate 101 may be exposed to physical or chemical damage. For example, cracks may occur in areas corresponding to the through hole CH of the display panel 100. For example, the hole crack detection part 186 may be exposed to a physical impact or the like in the areas corresponding to the through hole CH.

When the hole crack detection part 186 is disconnected by the cracks, the hole crack detection part 186 may not transmit electrical signals and thus may detect the cracks.

The hole crack detection part 186 may be formed coplanarly with the first touch electrode 185 and made of the same material as the first touch electrode 185.

The hole crack detection part 186 may be formed in a form of surrounding the through hole CH. For example, the hole crack detection part 186 may be formed in a form of having a curved surface corresponding to the through hole CH. For example, the hole crack detection part 186 may be formed in a form of two circles, but is not limited thereto.

The hole crack detection part 186 may be formed in the first non-display area NA1. For example, the hole crack detection part 186 may be formed between the display area AA and the dam DAM, for example, formed in a form of surrounding the hole crack detection part 186, but is not limited thereto.

A fourth metal layer 192 may be formed in an area that overlaps the dam DAM from a plan view as shown in FIG. 4.

The fourth metal layer 192 may be formed coplanarly with the first gate electrode 122 and made of the same material as the first gate electrode 122. For example, the fourth metal layer 192 may be formed on the substrate 101.

The fourth metal layer 192 may be an alignment mark required for the process of forming the through hole CH, but is not limited thereto.

FIG. 5 is an enlarged view of area B in FIG. 4 according to the embodiment of the present specification.

Referring to FIG. 5, the pattern 145′ may be formed on the fifth insulating layer 108 and the sixth insulating layer 109. The display device 100 according to the embodiments of the present specification may include a plurality of patterns 145′ (also referred to as a plurality of pattern structures 145′). For example, the patterns 145′ may be disposed to be spaced apart from each other.

The pattern 145′ may be formed coplanarly with the connection electrode 145 shown in FIG. 3. The pattern 145′ may include the first metal layer 145a, the second metal layer 145b, and the third metal layer 145c. The first metal layer 145a and the third metal layer 145c may be made of the same material, and at least one of the materials of the first metal layer 145a and the material of the third metal layer 145c may differ from the material of the second metal layer 145b. For example, the first metal layer 145a and the third metal layer 145c may include titanium (Ti), and the second metal layer 145b may include aluminum (Al), but the embodiments of the present specification are not limited thereto.

The support layer 112′ may be formed on the pattern 145′. For example, the support layer 112′ may be on the third metal layer 145c. The support layer 112′ may be made of an organic material. The support layer 112′ may be formed coplanarly with the second protective layer 112 shown in FIG. 3 and may be made of the same material as the second protective layer 112.

The organic layer 152′ may be formed on the support layer 112′. The organic layer 152′ may be formed coplanarly with the light emitting layer 152 shown in FIG. 3.

A path P may be a path of foreign substance such as oxygen or moisture. The path P (marked by an arrow) may be the fifth insulating layer 108, the sixth insulating layer 109, the support layer 112′, the pattern 145′, and the organic layer 152′. An end portion of the organic layer 152′ exposed through the through hole CH may become the path P.

According to the embodiments of the present specification, it is possible to provide a display device that increases the path P or prevents the easy permeation of foreign substance such as oxygen or moisture. For example, according to the embodiments of the present specification, it is possible to provide a structure of effectively disconnecting the organic layer 152′ to prevent the easy permeation of foreign substance such as oxygen or moisture.

The pattern 145′ may be formed coplanarly with the connection electrode 145, and the connection electrode 145 may have a predetermined thickness. For example, the connection electrode 145 may be formed coplanarly with the pattern 145′ and may be made of the same material as the pattern 145′. For example, since the pattern 145′ has a predetermined thickness in a vertical direction of the substrate 101, the organic layer 152′ can be disconnected more effectively. For example, the thickness of the organic layer 152′ may be smaller than the thickness of the pattern 145′. Therefore, the organic layer 152′ can be effectively disconnected due to the thickness of the pattern 145′ and the thickness of the support layer 112′.

Referring to FIG. 3, the connection electrode 145 may have a greater thickness than the first gate electrode 122 or the second gate electrode 132.

For example, the pattern 145′ formed coplanarly with the connection electrode 145 has a greater thickness than the pattern 145′ formed coplanarly with the first gate electrode 122 or the second gate electrode 132. In other words, the thickness of the first gate electrode 122 or the thickness of the second gate electrode 132 may be smaller than the thickness of the pattern 145′. Therefore, the pattern 145′ formed coplanarly with the connection electrode 145 can more effectively disconnect the organic layer 152′.

The pattern 145′ formed coplanarly with the connection electrode 145 may extend the path P.

Referring to FIG. 5, the sixth insulating layer 109 may be etched in the non-display area NA. For example, the organic layer 152′ may be disconnected by the pattern 145′ and the support layer 112′ formed on the pattern 145′. The pattern 145′ and the organic layer 152′ disconnected by the support layer 112′ formed on the pattern 145′ may be formed on the fifth insulating layer 108.

As the sixth insulating layer 109 is etched, the path P may increase as much as about the thickness of the sixth insulating layer 109. For example, the organic layer 152′ formed on the support layer 112′ and the organic layer 152′ formed on the fifth insulating layer 108 may be disposed to be spaced apart from each other. For example, the organic layer 152′ formed on the fifth insulating layer 108 may be in contact with the fifth insulating layer 108.

FIG. 6 is a cross-sectional view of a pattern according to the embodiment of the present specification.

Referring to FIG. 6, the support layer 112′ may be formed on the pattern 145′. An upper surface US of the support layer 112′ includes a curved surface. As shown, the upper surface US of the support layer 112′ may have a flat surface and a curved surface with a selected curvature. The flat portion FP of the upper surface US of the support layer 112′ is the farthest from an upper surface of the on third metal layer 145c. The pattern 145′ may include the first metal layer 145a, the second metal layer 145b, and the third metal layer 145c.

As shown in FIG. 6, the pattern 145′ can be implemented in a step structure of the pattern 145′ in which the second metal layer 145b is formed concavely by forming widths W1 and W3 of the first metal layer 145a and the third metal layer 145c that differ from a width W2 of the second metal layer 145b. For example, the width W1 of the first metal layer 145a or the width W3 of the third metal layer 145c may be greater than the width W2 of the second metal layer 145b.

Through a process of etching the second metal layer 145b or the like, the pattern 145′ may have the width W2 of the second metal layer 145b that differs from the widths W1 and W3 of the first metal layer 145a and the third metal layer 145c. For example, the first metal layer 145a may have a first protrusion length d1. The first protrusion length d1 may be d1=(W1−W2)/2.

For example, the third metal layer 145c may have a second protrusion length d2. The second protrusion length d2 may be d2=(W3−W2)/2.

When the third metal layer 145c is subjected to a process of decreasing the width W2 of the second metal layer 145b, the second protrusion length d2 may increase. For example, an end of the third metal layer 145c formed above the second metal layer 145b may be exposed.

When the second protrusion length d2 increases in the pattern 145′ without the support layer 112′, only the end of the third metal layer 145c may be exposed to disconnect an end of the third metal layer 145c in the pattern 145′.

When the end of the third metal layer 145c is disconnected, the path P cannot be increased, and the reliability of the display device 100 can also be degraded.

Therefore, when the support layer 112′ is formed on the pattern 145′, the end of the third metal layer 145 may be supported to effectively increase the second protrusion length d2. For example, since the support layer 112′ is formed, it is possible to effectively implement the step structure of the pattern 145′ in which the second metal layer 145b is formed concavely.

The support layer 112′ may have a lower width W4. Since the support layer 112′ may be made of an organic material, the lower width W4 of the support layer 112′ may be greater than the width W3 of the third metal layer 145c.

The path P of the etched pattern 145′ may be increased, for example, twice the first protrusion length d1 and the second protrusion length d2 compared to the path P of the non-etched pattern 145′.

The display device according to the embodiments of the present specification may be described as follows.

The display device according to the embodiments of the present specification may include a substrate including a display area and a non-display area, a first insulating layer formed on the substrate, a second insulating layer formed on the first insulating layer, patterns formed to be spaced apart each other on the second insulating layer in the non-display area, a support layer formed on each pattern and made of an organic material, and an organic layer formed on the first insulating layer, in which the organic layer disposed on the support layer may be disposed to be spaced apart from the organic layer formed on the first insulating layer.

According to one or more embodiments of the present specification, the organic layer formed on the first insulating layer may be in contact with the first insulating layer.

According to one or more embodiments of the present specification, the display area may further include a light emitting layer formed on the substrate, and the organic layer may be made of the same material as the light emitting layer.

According to one or more embodiments of the present specification, the pattern may include a first metal layer formed on the second insulating layer, a second metal layer formed on the first metal layer, and a third metal layer formed on the second metal layer, in which a material of the second metal layer may differ from at least one of a material of the first metal layer and a material of the third metal layer, and the support layer may be formed on the third metal layer.

According to one or more embodiments of the present specification, the material of the first metal layer may be the same as the material of the third metal layer.

According to one or more embodiments of the present specification, the first metal layer and the third metal layer may include titanium (Ti), and the second metal layer may include aluminum (Al).

According to one or more embodiments of the present specification, a width of the first metal layer may be greater than a width of the second metal layer.

According to one or more embodiments of the present specification, an upper surface of the support layer may be a curved surface.

According to one or more embodiments of the present specification, the display device may further include a gate electrode formed on the substrate of the display area, and a connection electrode formed on the gate electrode.

According to one or more embodiments of the present specification, the connection electrode may be formed coplanarly with the pattern and made of the same material as the pattern.

According to one or more embodiments of the present specification, a thickness of the gate electrode may be smaller than a thickness of the pattern.

According to one or more embodiments of the present specification, a thickness of the organic layer may be smaller than a thickness of the pattern.

According to one or more embodiments of the present specification, the display device may further include a protective layer formed on the connection electrode, and the support layer may be formed coplanarly with the protective layer and made of the same material as the protective layer.

According to one or more embodiments of the present specification, the display device may further include a first encapsulation layer formed on the support layer, a second encapsulation layer formed on the first encapsulation layer, a third encapsulation layer formed on the second encapsulation layer, and a touch buffer layer formed on the third encapsulation layer.

According to one or more embodiments of the present specification, the non-display area may include a first non-display area adjacent to the display area, and a second non-display area outside the first non-display area, and the touch buffer layer may be formed throughout the first non-display area and the second non-display area.

According to one or more embodiments of the present specification, the display device may further include a hole crack detection part formed on the touch buffer layer, and the hole crack detection part may be disposed in the first non-display area.

According to one or more embodiments of the present specification, the display device may further include a dam disposed in the non-display area, and a fourth metal layer formed on the substrate, and the fourth metal layer may overlap the dam when seen from a plan view.

According to one or more embodiments of the present specification, the display device may further include a gate electrode formed on the substrate of the display area, and the fourth metal layer may be formed coplanarly with the gate electrode and made of the same material as the gate electrode.

According to the embodiments of the present specification, it is possible to block moisture and oxygen that permeate toward the element along the organic layer through the hole.

According to the embodiments of the present specification, it is possible to block moisture and oxygen that permeate toward the element by providing the effective pattern that disconnects the organic layer near the hole. Therefore, it is possible to increase the lifetime of the display device and implement a reduction in production energy and the low-power driving of the manufacturing process.

The effects of the present specification are not limited to the above-described effects, and other effects that are not mentioned will be able to be clearly understood by those skilled in the art from the following description.

The above description is merely the exemplary description of the technical spirit of the present specification, and those skilled in the art to which the present specification pertains will be able to variously modify and change the present specification without departing from the essential characteristics of the present specification. In addition, the embodiments disclosed herein are not intended to limit the technical spirit of the present specification, but to describe the same, and the scope of the technical spirit of the present specification is not limited by these embodiments.

### DESCRIPTION OF REFERENCE NUMERALS

100: display device
AA: display area
NA: non-display area
NA1: first non-display area
NA2: second non-display area
CH: through hole
101: substrate
120: first thin film transistor
130: second thin film transistor
140: storage electrode
111: first protective layer
112: second protective layer
152: light emitting layer
171: first encapsulation layer
172: second encapsulation layer
173: third encapsulation layer
180: touch part
181: touch buffer layer
184: touch insulating layer

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area and a non-display area;
a first insulating layer on the substrate;
a second insulating layer on the first insulating layer;
patterns spaced apart from each other on the second insulating layer in the non-display area;
a support layer on each of the patterns, the support layer includes an organic material; and
an organic layer on the support layer and the first insulating layer,
wherein the organic layer on the support layer is disposed to be spaced apart from the organic layer on the first insulating layer.

2. The display device of claim 1, wherein the organic layer on the first insulating layer is in contact with the first insulating layer.

3. The display device of claim 2, wherein the display area further includes a light emitting layer on the substrate, and
wherein the organic layer is made of a same material as the light emitting layer.

4. The display device of claim 1, wherein the pattern includes:
a first metal layer on the second insulating layer;
a second metal layer on the first metal layer; and
a third metal layer on the second metal layer,
wherein a material of the second metal layer differs from at least one of a material of the first metal layer and a material of the third metal layer, and
wherein the support layer is on the third metal layer.

5. The display device of claim 4, wherein the material of the first metal layer is the same as the material of the third metal layer.

6. The display device of claim 4, wherein the first metal layer and the third metal layer include titanium, and
wherein the second metal layer includes aluminum.

7. The display device of claim 4, wherein a width of the first metal layer is greater than a width of the second metal layer.

8. The display device of claim 1, wherein an upper surface of the support layer is a curved surface.

9. The display device of claim 1, further comprising: a gate electrode on the substrate of the display area; and
a connection electrode on the gate electrode.

10. The display device of claim 9, wherein the connection electrode is disposed coplanarly with the pattern and is made of the same material as the pattern.

11. The display device of claim 9, wherein a thickness of the gate electrode is smaller than a thickness of the pattern.

12. The display device of claim 1, wherein a thickness of the organic layer is smaller than a thickness of the pattern.

13. The display device of claim 9, further comprising a protective layer on the connection electrode,
wherein the support layer is disposed coplanarly with the protective layer and is made of the same material as the protective layer.

14. The display device of claim 1, further comprising: a first encapsulation layer on the support layer;
a second encapsulation layer on the first encapsulation layer;
a third encapsulation layer on the second encapsulation layer; and
a touch buffer layer on the third encapsulation layer.

15. The display device of claim 14, wherein the non-display area includes a first non-display area adjacent to the display area, and a second non-display area outside the first non-display area, and
wherein the touch buffer layer is disposed throughout the first non-display area and the second non-display area.

16. The display device of claim 15, further comprising a hole crack detection part on the touch buffer layer,
wherein the hole crack detection part is disposed in the first non-display area.

17. The display device of claim 15, further comprising: a dam disposed in the non-display area; and
a fourth metal layer on the substrate,
wherein the fourth metal layer overlaps the dam from a plan view.

18. The display device of claim 17, further comprising a gate electrode on the substrate in the display area,
wherein the fourth metal layer is disposed coplanarly with the gate electrode and is made of the same material as the gate electrode.
